(19) United States
(12) Patent Application Publication
(10) Pub. No.: US 2025/0216708 A1
(43) Pub. Date: Jul. 3, 2025

(54) Photonic ICs with Photodiode and Modulator Temperature Compensation and Methods Therefor

(71) Applicant: Celestial AI Inc., Santa Clara, CA (US)

(72) Inventors: Sujit Handanhal Ramachandra, San Jose, CA (US); Subal SAHNI, La Jolla, CA (US); Matteo STAFFARONI, San Mateo, CA (US)

(21) Appl. No.: 18/911,820

(22) Filed: Oct. 10, 2024

Related U.S. Application Data
(60) Provisional application No. 63/616,430, filed on Dec. 29, 2023.

(51) Int. Cl. G02F 1/025; G02F 1/015

(52) U.S. Cl. CPC G02F 1/025; G02F 1/0155

(57) ABSTRACT

A package includes a substrate, a photonic integrated circuit (PIC) with a modulator and a photodetector, each equipped with a heater, and an electronic integrated circuit (EIC) featuring a temperature controller. The temperature controller is configured to regulate localized heating of the modulator and photodetector by controlling the respective heaters. This control mechanism is activated when the modulator or photodetector temperatures fall below a predetermined maximum operating temperature. The temperature controller may further modify the modulator and/or photodetector bias when a device temperature is in an extended operating temperature range.

### CROSS-REFERENCE TO RELATED APPLICATIONS

This application claims benefit to U.S. provisional patent application Ser. No. 63/616,430, entitled “Photonic Interconnect Platform for Memory and Compute”, filed on Dec. 29, 2023.

This application is related to U.S. patent application Ser. No. 18/123,083, entitled, “OPTICAL MULTI-DIE INTERCONNECT BRIDGE (OMIB)”, filed on Mar. 17, 2023, now U.S. Pat. No. 11,835,777; U.S. patent application Ser. No. 18/742,028, filed on Jun. 13, 2024; U.S. patent application Ser. No. 18/243,474, filed Sep. 7, 2023, now U.S. Pat. No. 12,124,095; U.S. patent application Ser. No. 18/376,474, filed Oct. 4, 2023; International Patent Application No. PCT/US23/15467, filed Mar. 17, 2023; U.S. patent application Ser. No. 18/751,021, filed on Jun. 21, 2024; U.S. patent application Ser. No. 18/751,086, filed on Jun. 21, 2024; U.S. patent application Ser. No. 18/751,101, filed on Jun. 21, 2024; U.S. patent application Ser. No. 18/751,105, filed on Jun. 21, 2024; U.S. patent application Ser. No. 18/757,084, filed on Jun. 27, 2024; and U.S. patent application Ser. No. 18/757,182; filed on Jun. 27, 2024.

Each publication, patent, and/or patent application mentioned in this specification is herein incorporated by reference in its entirety to the same extent as if each individual publication and/or patent application was specifically and individually indicated to be incorporated by reference.

### BACKGROUND

### Technical Field

The disclosed implementations relate generally to systems and methods used in data processing and communication, and in particular to those for optical data transfer.

### Context

Demands for artificial intelligence (AI) computing, such as machine learning (ML) and deep learning (DL), are increasing faster than can be met by increases in available processing capacity. This rising demand and the growing complexity of AI models drive the need to connect many chips into a system where the chips can send data between each other with low latency and at high speed. Performance when processing a workload is limited by memory and interconnect bandwidth. In many conventional systems, data movement leads to significant power consumption, poor performance, and excessive latency. Thus, multi-node computing systems that can process and transmit data between nodes quickly and efficiently may be advantageous for the implementation of (ML) models.

The subject matter discussed in this section should not be assumed to be prior art merely because of its mention in this section. Similarly, a problem mentioned in this section or associated with the subject matter provided as background should not be assumed to have been previously recognized in the prior art. The subject matter in this section merely represents different approaches, which in and of themselves can also correspond to implementations of the claimed technology.

### SUMMARY

In some aspects, the techniques described herein relate to a package including: a substrate configured to be electrically coupled with a heater power source on a first substrate side; a photonic integrated circuit (PIC) including a modulator with a first heater and a photodetector with a second heater, the PIC having a first side electrically coupled with a second side of the substrate; and an electronic integrated circuit (EIC) including a temperature controller configured to control localized heating of the modulator by the first heater in response to determining a first condition and/or localized heating of the photodetector by the second heater in response to determining a second condition, wherein the EIC has a first side electrically coupled with a second side of the PIC.

In some aspects, the techniques described herein relate to a method of temperature compensation in a PIC that includes a modulator and/or a photodetector, the method including: determining a sensed temperature in or near the PIC, wherein the sensed temperature is representative of a device temperature (a temperature of the modulator and/or the photodetector); and communicating the sensed temperature from the PIC to a temperature controller in an EIC and performing a first action, a second action, or both, based on the sensed temperature; wherein the first action includes: (1) determining a heater power control signal; (2) communicating the heater power control signal to a heater power source; (3) in the heater power source, generating heater power based on the heater power control signal; and (4) applying the heater power to a heater positioned near the modulator and/or the photodetector; and wherein the second action includes: (5) determining a device bias control signal; (6) communicating the device bias control signal to a bias source; (7) in the bias source, generating a bias based on the device bias control signal; and (8) applying the bias to the photodetector and/or the modulator.

In some aspects, the techniques described herein relate to a method of temperature compensation in a PIC that includes a modulator and/or a photodetector, the method including: receiving temperature information; using the temperature information to determine a heater power control signal and a bias control signal; using the heater power control signal to generate heater power and applying the heater power to a heater, wherein the heater locally heats the modulator and/or the photodetector; determining if the heater power is at a maximum level; and based on determining that the heater power is at the maximum level, using the bias control signal to modify a modulator bias level and/or a photodetector bias level.

In some aspects, the techniques described herein relate to a method of calibrating a thermal control system in a package that includes a temperature sensor, a PIC and an EIC, and wherein the PIC includes a modulator and a photodetector, the method including: looping back the modulator to the photodetector to enable measuring an optical modulation amplitude (OMA) of the modulator; setting a temperature of the PIC and the EIC at a target operating temperature (T₁) and letting the PIC and EIC reach thermal equilibrium; determining a first sensor signal (S_{T1}) to calibrate a sensor offset; setting the temperature of the PIC and the EIC at a second operating temperature (T₂) and letting the PIC and EIC reach thermal equilibrium; determining a second sensor signal (S_{T2}) to calibrate a sensor sensitivity slope; and using S_{T1} and S_{T2} to create a table or calibrate a model for operating temperatures between T₁ and T₂.

### BRIEF DESCRIPTION OF THE DRAWINGS

The technology will be described with reference to the drawings, in which:

FIG. 1 illustrates an example system including an example package with a PIC, an EIC, and an optional processor.

FIG. 2 illustrates an implementation in which the PIC also functions as interposer.

FIG. 3 illustrates example details of the package and the thermal control system.

FIG. 4 illustrates another example of details of the package and the thermal control system.

FIG. 5 illustrates a top view of an example implementation of the PIC with interfaces for multiple compute sections (that may be on the EIC) in a photonic mesh network.

FIG. 6 illustrates a cross-sectional view of a portion of an example package.

FIG. 7 illustrates an example top view of a photodiode implementation of a photodetector.

FIG. 8 illustrates an example top view of an electroabsorption modulator (EAM) implementation of a modulator.

FIG. 9 illustrates an example top view of the combination of the EAM and the heater.

FIG. 10 illustrates an example cross sectional view along section line A-A in FIG. 9 of the combination of the modulator and the heater (or the combination of the photodetector and the heater).

FIG. 11 illustrates an example method of temperature compensation in a system that includes a PIC with a modulator and/or a photodetector, a temperature controller, a heater power source, and a bias source.

FIG. 12 illustrates an example method of temperature compensation in a PIC that includes a modulator and/or a photodetector.

FIG. 13 illustrates another example method of temperature compensation in a PIC that includes a modulator and/or a photodetector.

FIG. 14 illustrates an example method of calibrating a thermal control system in a package with a PIC and an EIC.

In the figures, like reference numbers may indicate functionally similar elements. The systems and methods illustrated in the figures—and described in the Detailed Description below—may be arranged and designed in a wide variety of different implementations. Neither the figures nor the Detailed Description are intended to limit the scope as claimed. Instead, they merely represent examples of different implementations.

### DETAILED DESCRIPTION

Data processing and data communication systems increasingly use photonic components such as photonic integrated circuits (PICs) in combination with electronic integrated circuits (EICs) to transfer and otherwise process data quickly. PICs may be electrically coupled with EICs, and optically or photonically coupled with optic fibers, other PICs, and other photonic components and devices. An EIC may be mounted on a PIC or vice versa, and therefore the two may also be physically and thermally coupled.

A PIC may include a modulator to modulate light (that comes from an internal or external light source) with data provided by a driver circuit in the EIC (or other electronic device) and it may include a photodetector (PD), usually a photodiode, to detect information in modulated light. The photodetector in turn may interface with the/an EIC that further processes its signals and extracts its data.

Both modulators and photodetectors are physical devices whose behavior and performance depends on various physical parameters, including the temperature, bias voltages, and other factors. The affected behavior and performance include speed, dynamic range, sensitivity, insertion loss (IL), optical modulation amplitude (OMA), and other specifications. A set of required specifications may be reliably achieved over a temperature range known as the operating temperature range. The ‘natural’ operating temperature range of photonic devices such as modulators and photodetectors may be smaller than required for many practical applications. In those cases, temperature compensation may help to extend the usability of these devices.

As described in U.S. patent application Ser. No. 18/742,028, “An Optically Bridged Multicomponent Package with Extended Temperature Range”, methods to extend the operating temperature range of an electroabsorption modulator (EAM) include modifying its bias voltage or current dependent on the EAM's temperature or estimated temperature. A similar technique may be used for a photodetector. Very localized heating of the EAM and/or photodetector is another option. Heating is an expensive temperature compensation in terms of the required power, compared to modifying a bias. Yet, the technology disclosed herein may use heating before bias modification. To determine the amount of heating, some implementations measure only the modulator or photodetector temperature and heat the PIC locally at the site of the modulator or photodetector. Other implementations may further measure the overall PIC temperature.

Heating a device (modulator or photodetector) impacts its measured temperature, resulting in a negative feedback system where enough heat is applied to keep a device at a desired temperature, for example the highest target operating temperature. This works like a thermostat, and implementations take care that not more heat is applied than safe for the heater's reliability. When the device temperature drops below the desired temperature and maximum heat is applied, bias modification will provide further temperature compensation that keeps the device specifications within the desired range.

When a PIC includes both modulators and photodetectors, methods and systems for temperature compensation may be combined. In some implementations, both the EAM and the PD are temperature compensated by using localized heating, but only the EAM uses bias modification to further extend the operating temperature range. This document discloses systems and methods for the combined temperature compensation of photodetectors and modulators.

### Terminology

As used herein, the phrase “one of” should be interpreted to mean exactly one of the listed items. For example, the phrase “one of A, B, and C” should be interpreted to mean any of: only A, only B, or only C.

As used herein, the phrases at least one of and one or more of should be interpreted to mean one or more items. For example, the phrase “at least one of A, B, or C” or the phrase “one or more of A, B, or C” should be interpreted to mean any combination of A, B, and/or C. The phrase “at least one of A, B, and C” means at least one of A and at least one of B and at least one of C.

Unless otherwise specified, the use of ordinal adjectives first, second, third, etc., to describe an object, merely refers to different instances or classes of the object and does not imply any ranking or sequence.

The terms “comprising” and “consisting” have different meanings in this patent document. An apparatus, method, or product “comprising” (or “including”) certain features means that it includes those features but does not exclude the presence of other features. On the other hand, if the apparatus, method, or product “consists of” certain features, the presence of any additional features is excluded.

The term “coupled” is used in an operational sense and is not limited to a direct or an indirect coupling. “Coupled to” is generally used in the sense of directly coupled, whereas “coupled with” is generally used in the sense of directly or indirectly coupled. Coupled in an electronic system may refer to a configuration that allows a flow of information, signals, data, or physical quantities such as electrons between two elements coupled to or coupled with each other. In some cases, the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term “connected” is used to indicate a direct connection, such as electrical, optical, electromagnetic, or mechanical, between the things that are connected, without any intervening things or devices.

The term “configured” to perform a task or tasks is a broad recitation of structure generally meaning having circuitry that performs the task or tasks during operation. As such, the described item can be configured to perform the task even when the unit/circuit/component is not currently on or active. In general, the circuitry that forms the structure corresponding to configured to may include hardware circuits, and may further be controlled by switches, fuses, bond wires, metal masks, firmware, and/or software. Similarly, various items may be described as performing a task or tasks, for convenience in the description. Such descriptions should be interpreted as including the phrase configured to.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B”. This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms “substantially”, “close”, “approximately”, “near”, and “about” refer to being within minus or plus 10% of an indicated value, unless explicitly specified otherwise.

The following terms or acronyms used herein are defined at least in part as follows:

“Above”, “below”, “top”, and “bottom”—the bottom of a package is considered to be the side of the package where it is prepared for mounting on and electrical coupling with a printed circuit board or other substrate. Hence the top of the package is the opposing side. Devices inside the package, such as integrated circuits, substrates, interposers, etc. are considered to have a bottom towards the bottom of the package and a top towards the top of the package. Thus, in a package, below means towards the bottom of the package and above means towards the top of the package. However, integrated circuits may be mounted upside down (flip-chip mounting) and thus their top is oriented towards the bottom of the package and their bottom is oriented towards the top of the package. For an integrated circuit, the bottom is considered to be the side of the semiconductor substrate and the top is considered to be the side of its electronic devices, such as transistors and passive devices. In a chip, above means towards the top of the chip, and below means towards the bottom of the chip.
“AC”-alternating current
“AI”—artificial intelligence
“AMS”—analog/mixed-signal
“ASIC”—application-specific integrated circuit
“Bias”—a voltage or current applied to a device or circuit and needed to allow the device or circuit to function properly. In some cases, a bias provides power. The bias may be fixed or may be allowed to vary slowly compared to information carrying signals.
“CGRA”—coarse-grained reconfigurable architecture
“CMOS transistor”—complementary metal-oxide-semiconductor transistor
“CPU”—central processing unit
“DC”—direct current
“DL”—deep learning
“DSP”—digital signal processor
“EAM”—electroabsorption modulator
“EIC”—electronic integrated circuit
“FAU”—fiber array unit
“FET”—field-effect transistor
“FPGA”—field-programmable array
“GAAFET”—gate-all-around FET
“GC”—grating coupler
“GPU”—graphics processing unit
“HBT”—heterojunction bipolar transistor
“IC”—integrated circuit or chip—a monolithically integrated circuit, i.e., a single semiconductor die which may be delivered as a bare die or as a packaged circuit. For the purposes of this document, the term integrated circuit also includes packaged circuits that include multiple semiconductor dies, stacked dies, or multiple-die substrates. Such constructions are now common in the industry, produced by the same supply chains, and for the average user often indistinguishable from monolithic circuits.
“IL”—insertion loss
“JFET”—junction FET
“MCM”—multi-chip module
“ML”—machine learning
“MOS transistor”—metal-oxide-semiconductor transistor
“NMOS transistor”—N-type metal-oxide-semiconductor transistor
“OMA”—optical modulation amplitude
“OMIB”—optical multi-die interconnect bridge
“Operating temperature range”—the die temperature range specified by a device manufacturer over which device specifications published by the manufacturer are valid or guaranteed. Within a die, temperatures can vary. Often, the junction temperature of a transistor or diode is higher than the die temperature because the transistor or diode, or other surrounding devices, lose energy that is converted to heat.
“PCB”—printed circuit board
“PD”—photodetector
“PIC”—photonic integrated circuit
“PIN diode”—a diode with a positive doped region, an intrinsic region, and a negative doped region.
“PMOS transistor”—P-type metal-oxide-semiconductor transistor
“QCSE”—quantum-confined start effect
“QWC”—quantum well cell
“SI”—signal interface
“SOI”—silicon-on-insulator
“SPI”—serial peripheral interface
“TIA”—transimpedance amplifier
“TSV”—through-silicon via, an electrical connection between two opposing sides of a semiconductor wafer.
“XPU”—a processor, such as a central processing unit (CPU), a graphics processing unit (GPU), a coarse-grained reconfigurable architecture (CGRA), a field-programmable array (FPGA), or any other processor or AI accelerator.

### IMPLEMENTATIONS

Photodetectors, such as photodiodes, are commonly employed to convert optical energy into electrical energy. It is advantageous for a PD to capture a higher amount of light, as increased light absorption can lead to improved efficiency in converting optical energy to electric energy. Consequently, the PD becomes more responsive to low light levels with enhanced signal-to-noise ratio. However, the temperature and bias significantly impact the performance of PDs. Low temperature affects the energy band structure and reduces the absorption of photons. In a PIC, PDs may need to operate across a wide ambient temperature range (e.g., from 85° C. to 25° C.), but varying ambient temperatures can lead to undesirable fluctuations in the PD's performance.

The techniques implemented herein can maintain a stable PD performance over an extended temperature range (e.g., from 85° C. to 25° C.) by deploying a thermal control system. The thermal control system monitors temperatures of PDs and provides heating and/or bias compensation to widen the operating temperature range of the PDs. The thermal control system receives temperature-dependent electrical signals from a temperature sensor or it receives other information that measures or allows estimating or predicting the temperature of one or more PDs in a limited region of the PIC. It then determines whether heating must be applied, and if a bias adjustment must be made. It applies the heating and/or provides the bias to the PDs in the applicable region. When bias control is applied in at least a part of an extended temperature range, the behavior of the PDs due to the applied temperature-dependent bias correlates inversely with the PDs' temperature dependence, widening the operating temperature range to the extended temperature range. Therefore, the PD performance can be improved across the extended temperature range.

Similarly, these techniques can help provide a stable performance of modulators such as EAMs over an extended temperature range (e.g., from 85° C. to 25° C.). The thermal control system monitors temperatures of EAMs and provides heating and bias control compensation to widen the operating temperature range of the EAMs in the PIC's region of which the temperature was sensed, estimated, or predicted. The thermal control system receives temperature-dependent electrical signals from a temperature sensor or it receives other information that allows estimating or predicting the temperature of the EAMs. It then determines whether heating must be applied, and if a bias adjustment must be made. It applies the heating and/or provides the bias to the EAMs in the applicable region. In at least a part of an extended temperature range, the behavior of the EAMs due to the applied temperature-dependent bias correlates inversely with the EAMs' temperature dependence, widening the operating temperature range to the extended temperature range. Thus, the EAM performance can be improved across the extended temperature range.

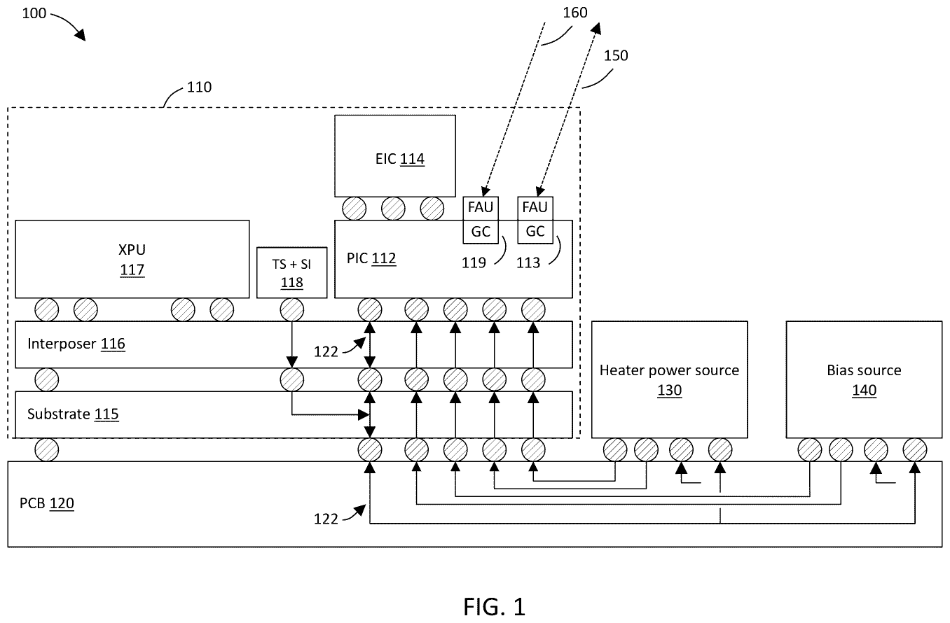

FIG. 1 illustrates an example system 100 including an example package 110 with a PIC 112, an EIC 114, and an optional processor (XPU 117). Apart from package 110, system 100 may include a printed circuit board (PCB 120), a heater power source 130, and a bias source 140. Package 110, heater power source 130, and bias source 140 may be mounted on PCB 120 with ball connectors, bumps or any other connector technology. For convenience, all such connectors are drawn here as arced circles. Connectors serve to provide electric couplings and may further serve to provide mechanical couplings and mechanical stability. Connectors not directly relevant to this description have not been drawn.

PCB 120 provides for interconnection of devices and modules mounted on it. It may include a signal bus 122, for example a serial bus such as a Serial Peripheral Interface (SPI) bus or Inter-Integrated-Circuit (I2C) bus. Implementations may use signal bus 122 to communicate between EIC 114, heater power source 130, bias source 140, and any other devices that provide information for EIC 114 or that must be controlled by EIC 114. PCB 120 further provides electrical connections that provide one or more biases from bias source 140 to package 110 and that provide heater power from heater power source 130 to one or more destinations in package 110.

Package 110 may include, for example, a substrate 115 and an interposer 116. Substrate 115 may not include any integrated devices. Substrate 115 provides at least partially vertical conductive pathways (also called through-vias or through-silicon-vias (TSVs)) to couple various signals into and out of PCB 120 and into and out of PIC 112. Substrate 115 is configured to receive heater power from heater power source 130 and to forward the heater power to the PIC and/or to receive bias levels from bias source 140 and to forward the bias levels to the PIC. Substrate 115 is further configured to couple PIC 112 and EIC 114 with signal bus 122. Interposer 116 is located between substrate 115 and both PIC 112 and XPU 117. XPU 117 may be, for example, a CPU, a GPU, a coarse-grained reconfigurable architecture (CGRA), a field-programmable array (FPGA), or any other processor or AI accelerator. Interposer 116 may be, for example, a silicon interposer, or any other component that can be placed between semiconductor and other devices that provided electrical routing of signals between the devices, and that may additionally help provide thermal management. In this example, interposer 116 may provide electrical coupling between XPU 117, PCB 120, EIC 114, and any other devices and systems that are within or coupled with the package. For example, interposer 116 may couple a package temperature sensor 118 with signal bus 122. Package temperature sensor 118 may sense a package temperature that may be representative of the temperature of a modulator and/or photodetector in PIC 112. PIC 112 may be coupled with an optical fiber 150 via optical interface 113, which may include, for example, a grating coupler (GC) and a fiber array unit (FAU).

Bias source 140 may include, for example, a converter which may include a DC-to-DC converter, a charge pump, or a linear regulator or other converter, and which receives input power at one voltage level and provides one or more biases at other voltage levels, or at current levels. The converter may be fixed or controllable. If it is controllable, bias source 140 may further include a signal interface that is coupled with signal bus 122 and that controls the level of the bias or biases based on signals it receives from EIC 114 via signal bus 122.

Heater power source 130 may also include a converter with a DC-to-DC converter, a charge pump, a linear regulator or other converter that receives input power at one voltage level and that provides heater power at one or more other voltage levels or current levels. The converter may be fixed or controllable. If it is controllable, heater power source 130 may further include a signal interface SI that is coupled with signal bus 122 and that controls the level of the heater power (for example, in the form of controlled heater currents) based on signals it receives from signal bus 122.

The level of activity of EIC 114 and XPU 117 may impact the die temperature of PIC 112, and thus, indirectly, the junction temperatures of devices operating within PIC 112. This includes the junction temperature of photodiodes (or more generally, devices included in photodetectors) and of EAMs (or more generally, devices included in modulators). The PIC's operating temperature range is the (presumed average) die temperature range within which the PIC operates according to its published specifications. However, the junction temperatures at specific devices within the PIC may be higher or lower than the average die temperature. The performance of these devices depends not only on their junction temperature, but also on their bias (voltage or current), and potential other factors. To operate the devices optimally, given the PIC die temperature as impacted by the ambient temperature including effects caused by the level of activity of EIC 114 and XPU 117, an implementation may provide a thermal control system that applies bias and temperature compensation as disclosed herein. The bias and temperature compensation result in an extended operating temperature range for the PIC.

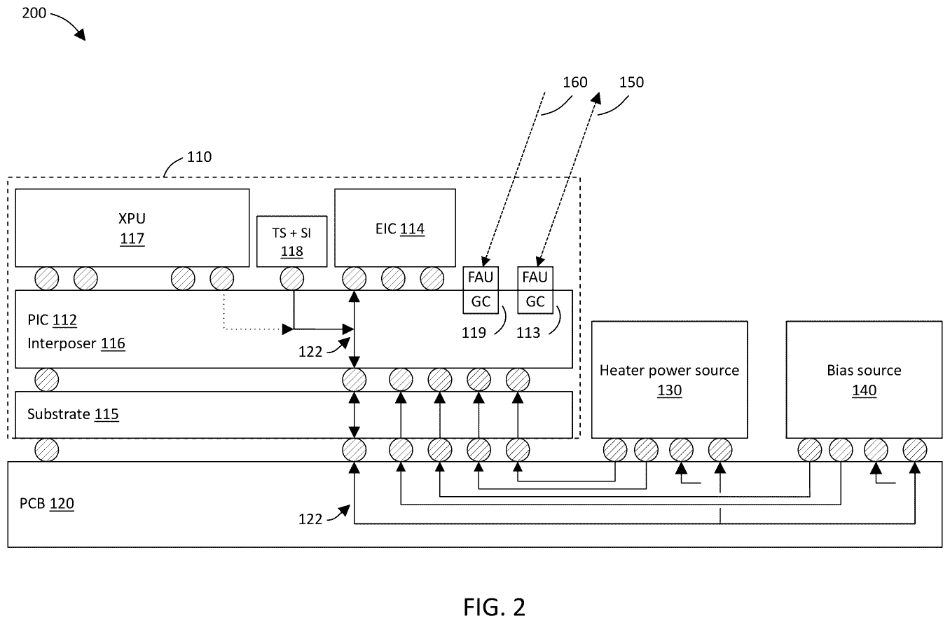

FIG. 2 illustrates an implementation in which the PIC 112 also functions as interposer 116. In this implementation, PIC 112 directly provides passage for signals between XPU 117 and EIC 114, as well as for power and signals between XPU 117 and any other devices that are coupled with PCB 120 or PIC 112/interposer 116. It may also couple package temperature sensor 118 and/or XPU 117 with signal bus 122. In some implementations, PIC 112 couples package temperature sensor 118 with EIC 114 not via signal bus 122 but with dedicated electrical pathways.

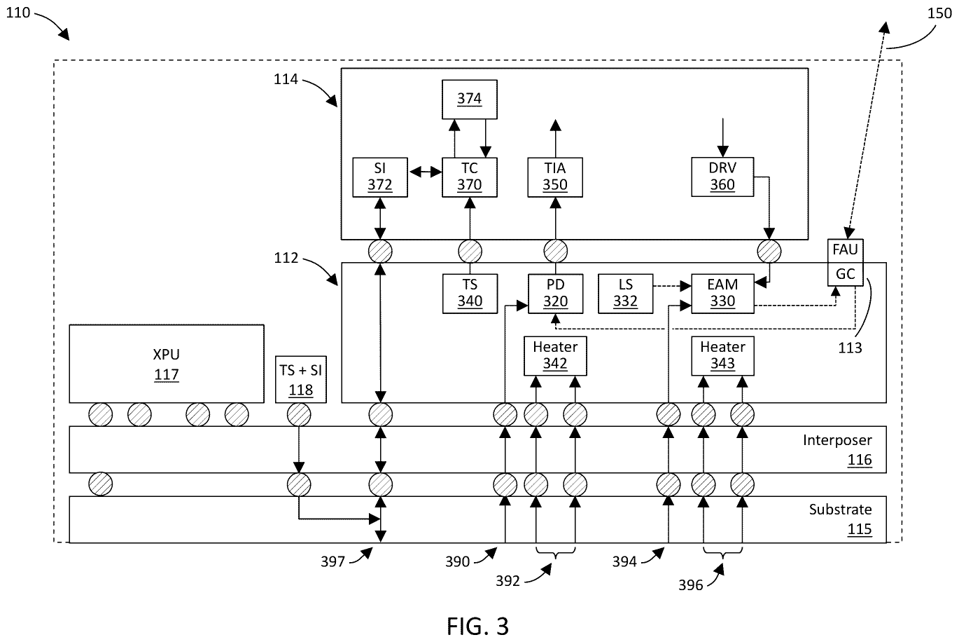

FIG. 3 illustrates example details of package 110 and the thermal control system. Electrical couplings such as metal tracks, vias, and wires have been drawn as solid lines. Optical couplings such as waveguides and optical fibers have been drawn as lines with short dashes. On a surface on the side of substrate 115, e.g., the bottom surface, the package has several interconnect areas, or landing pads, for the ball connectors or bumps that may couple package 110 with PCB 120. For example, interconnect area 397 provides landing pads for coupling package 110 with external parts of signal bus 122. Interconnect area 390 provides one or more landing pads for coupling package 110 with a bias input of photodetector 320, for example a photodiode. Interconnect area 392 provides landing pads for coupling heater power for heater 342 into package 110. Interconnect area Interconnect area 394 provides one or more landing pads for coupling package 110 with a bias input of modulator 330, which may be an EAM, in PIC 112. Interconnect area 396 provides landing pads for coupling heater power for heater 343 into package 110. Signals, bias, and/or power for PIC 112, EIC 114, XPU 117, and package temperature sensor 118 may pass through substrate 115 and interposer 116.

Whereas both photodetector 320 and modulator 330 receive a bias, which can be a semi-stationary voltage or current, amplifier 350 and driver 360 may be coupled for fast changing signals only, e.g., via a capacitor, or for both fast changing and slow changing signals, e.g., without a capacitor. Loosely speaking, the bias is said to be “DC coupled” (direct current) whereas the data signals may be either DC coupled or “AC coupled” (alternating current). Photodetector 320 may be a photodiode, which typically needs to be “reverse biased” to operate, meaning that its anode must be at a lower voltage than its cathode. In case the photodiode is biased with a voltage, the bias voltage is applied to its anode with reference to its cathode and is negative. In case the photodiode is biased with a current, the current is sourced into the cathode, or sinked from the anode. Modulator 330 may be an EAM and may also be based on a diode. In that case, the diode again must be reverse biased for the modulator to operate. The EAM is usually biased with a voltage, and this voltage too must be negative.

Heater 342 is located very close (within a distance of thirty (30) microns) to photodetector 320, and in some implementations heater 342 is located directly above or under photodetector 320. Heater 343 is located very close (within a distance of thirty (30) microns) to modulator 330, and in some implementations heater 343 is located directly above or under modulator 330. It has been found that a heater can locally impact the temperature of PIC 112 within a radius of up to a few tens of microns. For this reason, the heaters can help provide temperature compensation for individual photodetectors and modulators. However, this may also require that individual measurements or estimates of those devices' temperatures are available.

PIC 112 may further include a light source 332, and a temperature sensor 340 or multiple temperature sensors. PIC 112 may act as another interposer for power, bias, and signals for EIC 114, such as for example with signal bus 122. EIC 114 may include an amplifier 350, for example a transimpedance amplifier (TIA) coupled with photodetector 320 in PIC 112; a (driver 360), coupled with a signal input of modulator 330 in PIC 112; a temperature controller 370, coupled with a signal output of temperature sensor 340 in PIC 112, and coupled with a signal interface 372; and an optional memory 374 to hold a table, software, or firmware that temperature controller 370 can uses for converting temperature information to bias control signals and heater power control signals that extend the effective operating temperature ranges of photodetector 320 and modulator 330. Signal interface 372 couples temperature controller 370 with signal bus 122 to allow it to receive information and dispatch bias control signals for bias source 140 and heater power control signals for heater power source 130.

Temperature controller 370 can use hardware, software, or firmware (or any combination of these), which implements logic configured to determine when and how much a thermal variable, such as a device temperature, diverges from an optimal range. Temperature controller 370 can use a look-up table, access a database, compute a value using thermal model, or use some other means to determine when and how much to vary a device's (or group of devices) heater power and/or bias. In one implementation, temperature controller 370 obtains heater power control data and bias control data by using a table, a database, or another suitable data structure. For example, a table can have multiple rows and columns where each row has at least a first column to represent a present temperature (or signal associated with the temperature), a corresponding second column to represent associated heater power control data, and a corresponding third column to represent associated bias control data.

Optical interface 113 may receive optical signals from optical fiber 150 and send the received optical signals to photodetector 320, for example via one or more photonic waveguides and other photonic devices. Photodetector 320 converts the optical signals to electrical signals, which it sends to amplifier 350. Amplifier 350 amplifies the electrical signals and prepares them for digitization. Ultimately, EIC 114 may process the digitized signals and/or send the digitized signals to XPU 117 and/or other destinations.

Driver 360 receives electrical signals, for example from XPU 117 and/or other sources, or from processes internal to EIC 114, and prepares the electrical signals for modulation by modulator 330. Modulator 330 receives light, for example unmodulated light, from light source 332, and modulates the light with information received from driver 360. Modulator 330 may send the modulated light to optical fiber 150 via one or more photonic waveguides and/or other photonic devices and optical interface 113.

Although FIG. 3 shows photodetector 320 configured for receiving photonic signals via optical interface 113 and modulator 330 configured for transmitting photonic signals via optical interface 113, further photodetectors may receive photonic signals from other sources and further modulators may transmit photonic signals to other destinations. For example, although FIG. 3 shows optical interface 113 as a single interface for incoming and outgoing optical signals, an implementation may have one or more dedicated optical interfaces for incoming optical signals, one or more dedicated optical interfaces for outgoing optical signals and/or one or more dedicated optical interfaces for incoming unmodulated light.

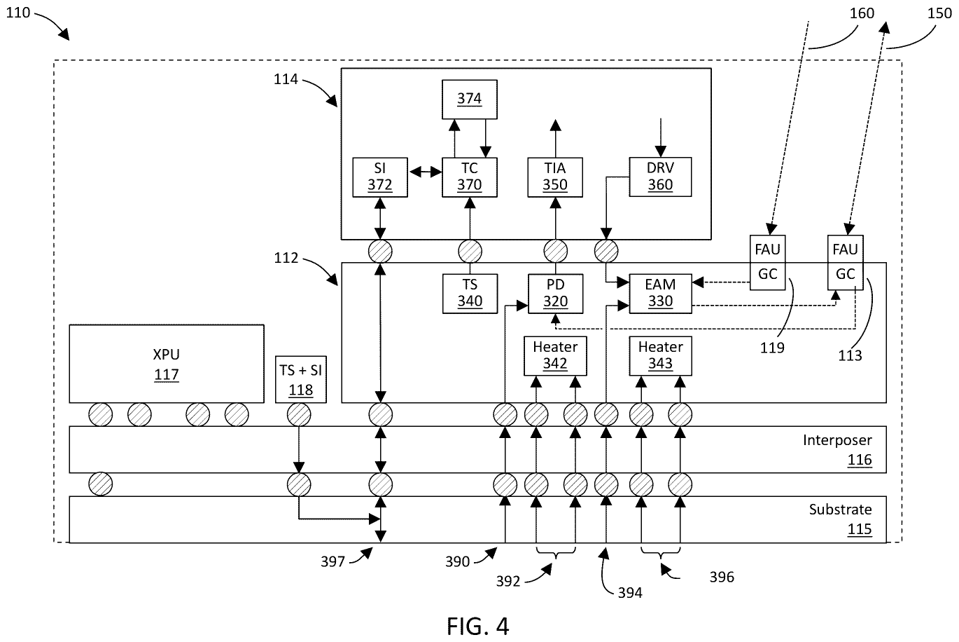

FIG. 4 illustrates another example of details of package 110 and the thermal control system. In this implementation, PIC 112 does not include a light source 332, but instead modulator 330 receives light that may be unmodulated via optical interface 119 from an external optical fiber 160.

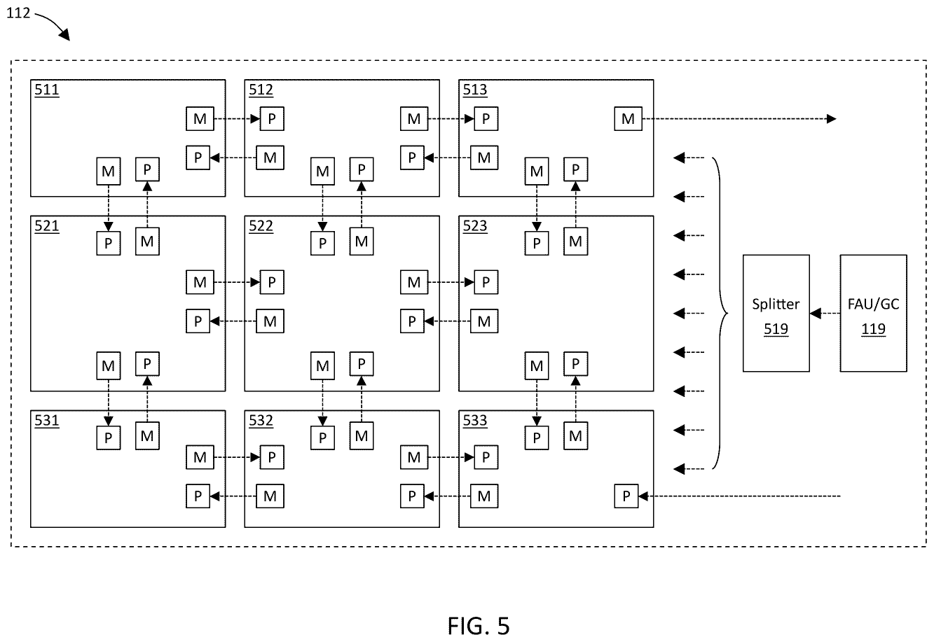

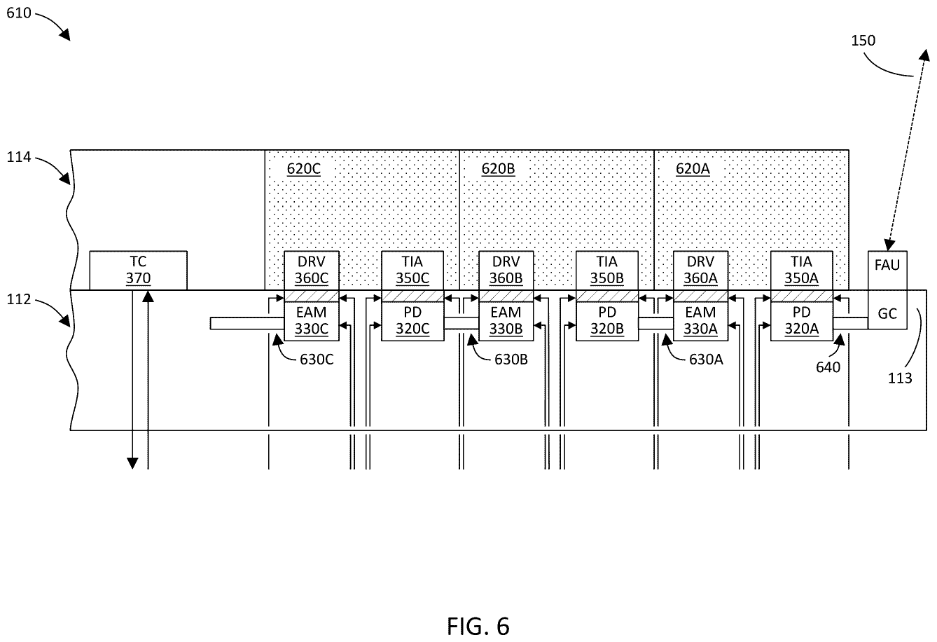

FIG. 5 illustrates a top view of an example implementation of PIC 112 with interfaces for multiple nodes (that may be on EIC 114) in a photonic mesh network. A node, as used in FIG. 5 or FIG. 6 may be or include a compute section, a communication network node, a memory section, a memory interface or any other item that may require access via a mesh network. In this example, node 511, node 512, and node 513 sit in a first row; node 521, node 522, and node 523 sit in a second row; and node 531, node 532, and node 533 sit in a third row. Each node can photonically interface with each of its nearest neighbors via a modulator (M) and photodetector (P) pair. Dependent on its location on the die (e.g., corner, edge, inside), there are two or more modulator-photodetector pairs. Additionally, node 513 may have an extra modulator for communication with another destination, e.g., off-chip via optical interface 113 (not drawn), and node 533 has an extra photodetector for communication from another source, e.g., off-chip via optical interface 113. In this example, PIC 112 receives unmodulated light at optical interface 119. The splitter 519 splits the unmodulated light in multiple beams, each for one or more compute sections in the mesh network. Eventually, a modulator receives a branch of the unmodulated light and modulates it with data for a photodetector in its nearest neighbor. There may be multiple types of modulators and photodetectors in PIC 112. For example, for communication with its nearest neighbor, a compute section may use a first type of modulator and a first type of photodetector. For off-chip communication, a compute section may use a second type of modulator and a second type of photodetector. For other destinations and sources, a compute section may use a third type of modulator and a third type of photodetector. The different types may have different operating profiles (i.e., behavior and specifications as a function of temperature and bias) and may therefore need different or even individual temperature compensation.

FIG. 6 illustrates a cross-sectional view of a portion of an example of package 610. EIC 114 may include multiple node(s) 620 (node(s) 620A-C are shown) that each include, for example, compute section, a communication network node, a memory section, a memory interface, etc., and an analog/mixed-signal (AMS) circuit to interface with PIC 112. The node may process data contained in received messages, and a message router may receive messages via PIC 112 and also transmit messages via PIC 112. Each of the AMS circuits may include an amplifier 350A-C (e.g., a TIA) and/or a driver (driver 360A-C) electrically coupled with a photodetector 320A-C and/or a modulator 330A-C in PIC 112, respectively. Electrical connections between EIC 114 and PIC 112 may be realized via ball connectors, bumps, etc., but have not been drawn in FIG. 6. FIG. 6 shows drivers situated directly above modulators and heaters, and transimpedance amplifiers situated directly above photodetectors and heaters. However, in implementations, the drivers and transimpedance amplifiers may be situated directly below the modulators and heaters and the transimpedance amplifiers may be situated directly below the photodetectors and heaters. In further implementations, the drivers and transimpedance amplifiers may not be situated directly above (or below) the modulators and photodetectors (with heaters), but with an offset of up to a few tens of microns, for example 30 microns for high-speed data or up to a few hundreds of microns, for example 300 microns for medium-speed data, or even farther for low-speed data, to lower electrical or thermal interference.

The node(s) 620 in EIC 114 may be optically coupled by waveguide(s) 630A-C in PIC 112, so that communication from for example node(s) 620A to node(s) 620C may travel via waveguide(s) 630A, node(s) 620B, and waveguide(s) 630B. In some implementations the light source(s) for the modulators may be on-chip, whereas in other implementations the light source(s) may be off-chip, and light is provided through one or more optical interfaces.

FIG. 6 shows a bias coupling for each photodetector 320A-C, and for each modulator 330A-C. Bias couplings come in from the bottom of PIC 112 and are single ended. FIG. 6 further shows heaters (diagonally hatched areas on top of the modulators and photodetectors) with heater power (one connection on each side) coming from the bottom of PIC 112.

An incoming message from optical fiber 150 travels through optical interface 113 and waveguide 640 to photodetector 320A, which converts the optical signal to an electrical signal for amplifier 350A and for further processing in node(s) 620A. An outgoing message from node(s) 620A travels to optical fiber 150 via a driver and a modulator (both not shown), and optical interface 113. Photodetectors optically coupled with optical interface 113 (e.g., for inter-chip communication) may be of a different type than photodetectors used for communication between different parts of EIC 114 (e.g., intra-chip communication). For example, a photodetector used for inter-chip communication may be an edge PD or corner PD. Thus, PIC 112 may host multiple types of photodetectors, and similarly it may host multiple types of modulators. Each type of photodetector or modulator may have its own dependencies on bias and temperature, therefore, temperature controller 370 stores heater power control data and bias control data as a function of the temperature for each type of photodetector and each type of modulator. In some implementations, temperature controller 370 stores heater power control data and bias control data as a function of the temperature for each some or all individual photodetectors and modulators. An implementation may have multiple units of heater power source 130 and bias source 140, or conversely, bias source 140 may generate a separate bias level for each type of photodetector and/or modulator, and heater power source 130 may generate a separate heater power level for each type of photodetector and/or modulator. Some implementations may have multiple units of temperature controller 370, each one dedicated to a type of photodetector or modulator. Implementations may use temperature controllers at a finer granularity, for example the implementations may dedicate a slice of a temperature controller's time to each type in a cluster of node(s) 620, in one of the node(s) 620, or even dedicated to individual photodetectors and modulators. Temperature information for the temperature controller(s) may come from temperature sensors on the PIC. Generally, the finer the temperature control granularity, the more temperature sensors may be needed. For example, an implementation that compensates for temperature dependence of all devices in a cluster of node(s) 620 may need one temperature sensor in that cluster. An implementation that compensates for temperature dependence of all devices in individual node(s) 620 may need one temperature sensor per node(s) 620.

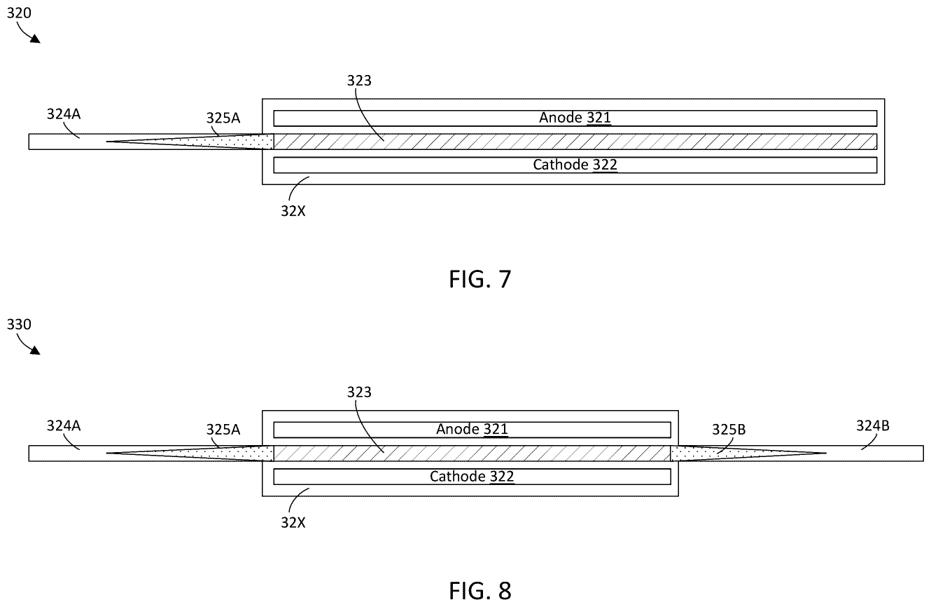

FIG. 7 illustrates an example top view of a photodiode implementation of photodetector 320. The photodiode is a PIN diode (with Positive-doped, Intrinsic, and Negative-doped regions) where the photonic signal traverses the intrinsic (net undoped) area between the positive doped anode and the negative doped cathode of the diode. The photodiode needs to convert all optical power incident on it into photo current. Thus, the photodiode has a long aspect ratio where the lengths of the anode, intrinsic region, and cathode greatly exceed the widths.

Modulated light travels through waveguide 324A into semiconductor waveguide 323 which is, or includes, the intrinsic semiconductor material. A PD generally has no exit for photonic signals, so only waveguide 324A has been drawn. Waveguide 324A has a tapered tip 325A, for example made of polycrystalline silicon (or poly) to minimize light losses in the transition to semiconductor waveguide 323. Semiconductor waveguide 323 (and parts of anode 321 and cathode 322) may be made of germanium silicon (GeSi), for example. Anode 321 is doped to have a shortage of free electrons (P-type semiconductor material) and cathode 322 is doped to have an excess of free electrons (N-type semiconductor material).

The photodiode is zero-biased or reverse biased, that is, the anode is at the same or a lower voltage than the cathode, and when there is no light traveling into semiconductor waveguide 323, only a leakage current known as the dark current flows between the cathode and the anode. When light enters semiconductor waveguide 323, the current can strongly increase, dependent on the optical power and on the photodiode bias. To capture a signal that is proportional to the optical power, the implementation must measure the fast or AC changes in the current.

In some implementations, the photodetector 320 comprises a material selected from one or more of germanium, silicon, an alloy of germanium, an alloy of silicon, a III-V material based on indium phosphide (InP), and a III-V material based on gallium arsenide (GaAs). In some implementations, photodetector 320 comprises about 99% germanium and about 1% silicon (e.g., more than 99% germanium and less 1% silicon).

FIG. 8 illustrates an example top view of an EAM implementation of modulator 330. The EAM is also made of a PIN diode. However, the insertion loss of the EAM may not be more than the application's link budget allows, therefore, it may be shorter than the PIN diode of photodetector 320. For example, whereas in a manufacturing process the PIN diode in photodetector 320 may have a length of 80 to 150 microns, the PIN diode in modulator 330 may have a length of 30 to 80 microns.

Light that may be unmodulated travels through waveguide 324A into semiconductor waveguide 323 which is, or includes, the intrinsic semiconductor material, and out of semiconductor waveguide 323 at the other end into waveguide 324B. Waveguide 324A has a tapered tip 325A, for example made of polycrystalline silicon (or poly) to minimize light losses in the transition to semiconductor waveguide 323 and similarly, waveguide 324B has a tapered tip 325B to minimize light losses in the transition from semiconductor waveguide 323. Semiconductor waveguide 323 (and parts of anode 321 and cathode 322) may be made of germanium silicon (GeSi), for example. Anode 321 is doped to have a shortage of free electrons (P-type semiconductor material) and cathode 322 is doped to have an excess of free electrons (N-type semiconductor material).

The PIN diode is zero-biased or reverse biased, that is, the anode is at the same voltage as or a lower voltage than the cathode. Using the Franz-Keldysh effect, an implementation varies the optical absorption level of semiconductor waveguide 323 by changing the voltage across the PIN diode. Thus, an implementation as EAM uses the voltage over the PIN diode (or the current through the diode) as a parameter to modulate the light that travels through semiconductor waveguide 323. For example, in an implementation the cathode may receive an AC signal that has a swing of −1 to +1 V. To ensure that the PIN diode is always reverse biased, if the bias is applied to the anode, its highest value must be lower than −1 V, for example −1.2 V. For an implementation in which the signal is DC coupled and has a swing of 0 to 2 V, the maximum value of the bias voltage should be lower than 0 V, for example, −0.2 V.

In some implementations, the modulator 330 comprises a material selected from one or more of germanium, silicon, an alloy of germanium, an alloy of silicon, a III-V material based on indium phosphide (InP), and a III-V material based on gallium arsenide (GaAs). In some implementations, modulator 330 comprises about 99% germanium and about 1% silicon (e.g., more than 99% germanium and less 1% silicon).

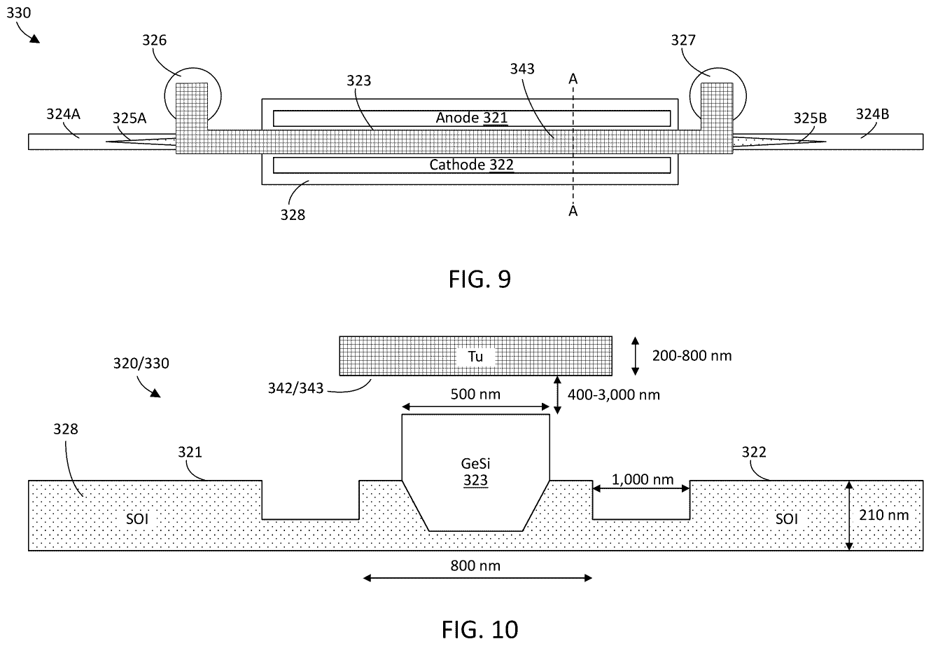

FIG. 9 illustrates an example top view of the combination of modulator 330 and heater 343 (the combination of photodetector 320 and heater 342 is similar). In this example, heater 343 is placed over the PIN diode (e.g., on the side towards EIC 114), and it is in the shape of a metal strip. In other implementations it may be snake-shaped instead of straight, and it may be silicon instead of metal. Different materials have different resistivities, and different long-term effects from heat. Some implementations may use a layer of thick metal that is already available in the PIC's metal stack, for example tungsten (Tu), titanium nitiride (TiN), or copper (Cu). Other implementations may use polysilicon or doped silicon. At the ends of the heater, the metal may turn sideways to connect to via 326 (and in the case of a modulator) via 327, which goes through the bottom of PIC 112 towards substrate 115 and PCB 120. In an implementation, the length of heater 343 exceeds the length of semiconductor waveguide 323, for example 100 microns tungsten versus 80 microns of semiconductor waveguide 323, and heater 343 is located between 200 and 3,000 nanometers above semiconductor waveguide 323. If the heater is closer than 200 nanometers above or below the photodetector or modulator, the risk of electrical interference may become unacceptable. If the heater is farther than 3,000 nanometers away from the device, the heating is not localized anymore, and may become less effective.

FIG. 10 illustrates an example cross sectional view along section line A-A in FIG. 9 of the combination of modulator 330 and heater 343 (or a similar section line in the combination of photodetector 320 and heater 342 of FIG. 3). In this cross section, anode 321 is on the left, and cathode 322 is on the right of a layer of silicon-on-insulator (SOI 328). Semiconductor waveguide 323 may be composed of GeSi and have a length (between anode 321 and cathode 322) of, for example, 500 nm. Some 400 to 3,000 nm above semiconductor waveguide 323 sits heater 342, which may have a width of 900 nm and therefore cover semiconductor waveguide 323 and its flanks. Heater 343 may have a thickness of 200 to 800 nm.

Many variations of the EAM and photodiode designs are possible, and shapes and sizes mentioned here are idealized examples. Materials may vary between implementations, and thicknesses of layers may vary because the etching process doesn't follow precise orthogonal plans. All such variations are within the scope and ambit of this disclosure.

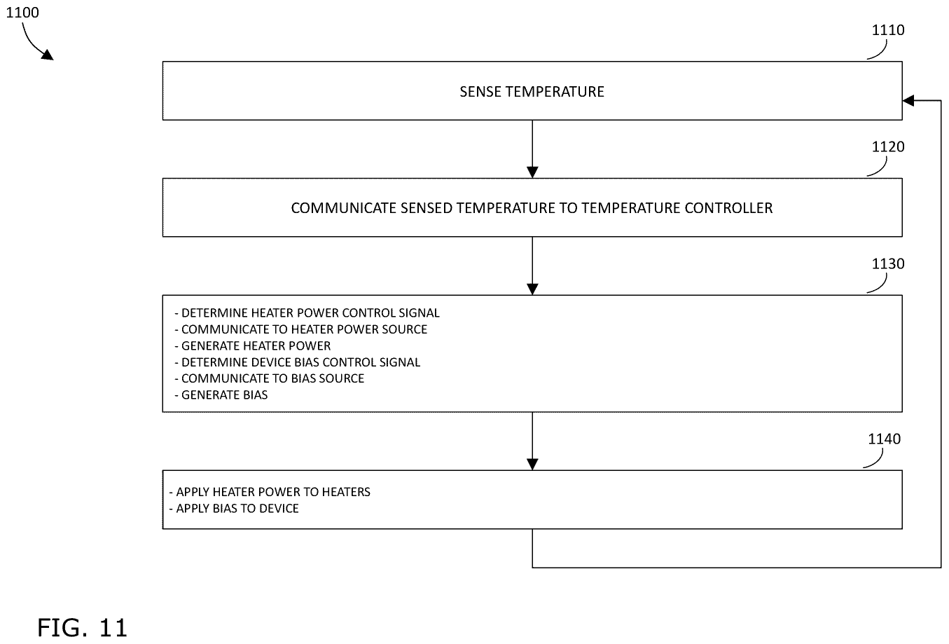

FIG. 11 illustrates an example method 1100 of temperature compensation in a system that includes a PIC with a modulator and/or a photodetector, a temperature controller, a heater power source, and a bias source. The modulator may be an EAM, and the photodetector may be a photodiode. The PIC may be in a package and may be combined with an EIC. The temperature controller may be included in the EIC. Method 1100 comprises:
1110—sensing a temperature. The temperature may be a temperature in the PIC, a temperature in a package that includes the PIC, or another temperature that is associated with or that allows estimating or predicting the temperature of the modulator and/or the photodetector.
1120—communicating the sensed temperature to the temperature controller.
1130—in the temperature controller, determining a heater power control signal and a device bias control signal. The temperature controller communicates the heater power control signal to the heater power source and the device bias control signal to the bias source. The heater power source generates heater power, and the bias source generates a bias. The temperature controller may determine the heater power control signal and the device bias control signal directly from the sensed temperature, for example by using a lookup table or a processor to calculate their values, or it may determine them indirectly, for example by first calculating a difference with a desired temperature, applying one or more thresholds to the difference, and determining the heater power control signal and the device bias control signal based on the results of the one or more thresholds. The heater power control signal and the device bias control signal may include instructions that the heater power and/or the bias should be the same as the heater power and/or the bias at the desired temperature, or that they should be different. The heater power and the bias, as a function of the sensed, estimated, or predicted temperature, may have been optimized for the OMA of the modulator and the dynamic range of the photodetector.
1140—applying the heater power to a heater, and applying the bias to the modulator and/or the photodetector. The method may return to 1110 to continuously, or at selected times or intervals, monitor the temperature and optimize performance of the modulator and/or the photodetector.

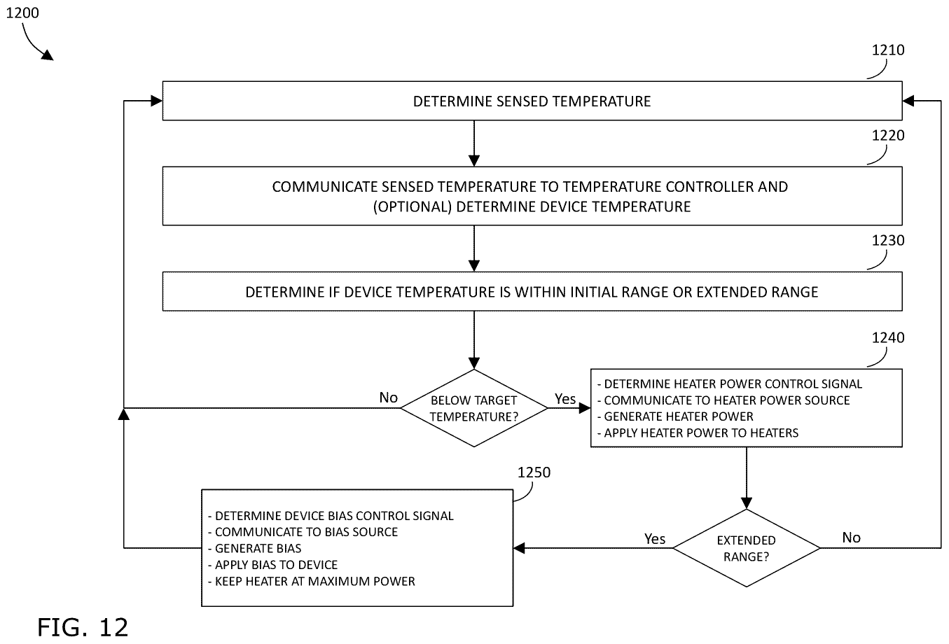

FIG. 12 illustrates an example method 1200 of temperature compensation in a PIC that includes a modulator and/or a photodetector, and a sensor. The photodetector may be or include a photodiode and the modulator may be or include an EAM. In some implementations, the sensor is not in the PIC, but nearby. In some cases, the PIC includes part of the sensor, for example two transistors or two diodes, and an EIC includes another part, for example two current sources or current sinks that bias the two transistors or two diodes, and an amplifier that amplifies a differential voltage between the two transistors or two diodes. Method 1200 comprises:
1210—Determining the temperature sensed by the sensor (the sensed temperature). The sensed temperature may be representative of a temperature of the modulator and/or the photodetector.
1220—Communicating the sensed temperature to the temperature controller and determining a device temperature from the sensed temperature. Some implementations communicate an analog signal that includes the sensed temperature, and other implementations communicate a digital signal. Yet other implementations communicate any other signal that includes the sensed temperature. In some cases, the temperature controller directly reads the device temperature, and in other cases the temperature controller uses the sensed temperature to estimate or predict the device temperature (i.e., the modulator and/or the photodetector temperature).
1230—Determining if the device temperature is different from a target operating temperature. If the device temperature equals or is higher than the target operating temperature, the method may return to 1210.
1240—Based on determining that the device temperature is different than the target operating temperature: (1) determining a heater power control signal; (2) communicating the heater power control signal to a heater power source; (3) in the heater power source, generating heater power based on the heater power control signal; and (4) applying the heater power to a heater.

Some implementations combine 1230 and 1240. For example, an implementation may determine heater control signals for temperatures including the target operating temperature, for which it may determine a heater power control signal that indicates that no heater power is generated. Another implementation may generate the heater power control signal in a thermostat loop, where the heater power to be generated depends on a difference between the device temperature and a target operating temperature.
1250—Determining if the device temperature is within an extended range. If the device temperature is not within the extended range, the method may return to 1210. The extended range may start at a device temperature below which heater power cannot be further increased to avoid reliability issues or decreased device or heater lifetime due to electromigration or due to any other disintegration of a device or the heater.
1260—Based on determining that the device temperature is within the extended range: (5) determining a device bias control signal; (6) communicating the device bias control signal to a bias source; (7) in the bias source, generating a bias based on the device bias control signal; (8) applying the bias to the photodetector and/or the modulator; and (9) keeping the heater at a maximum heater power. The device bias control signal may include a modulator bias control signal and/or a photodetector bias control signal. The method may return to 1210.

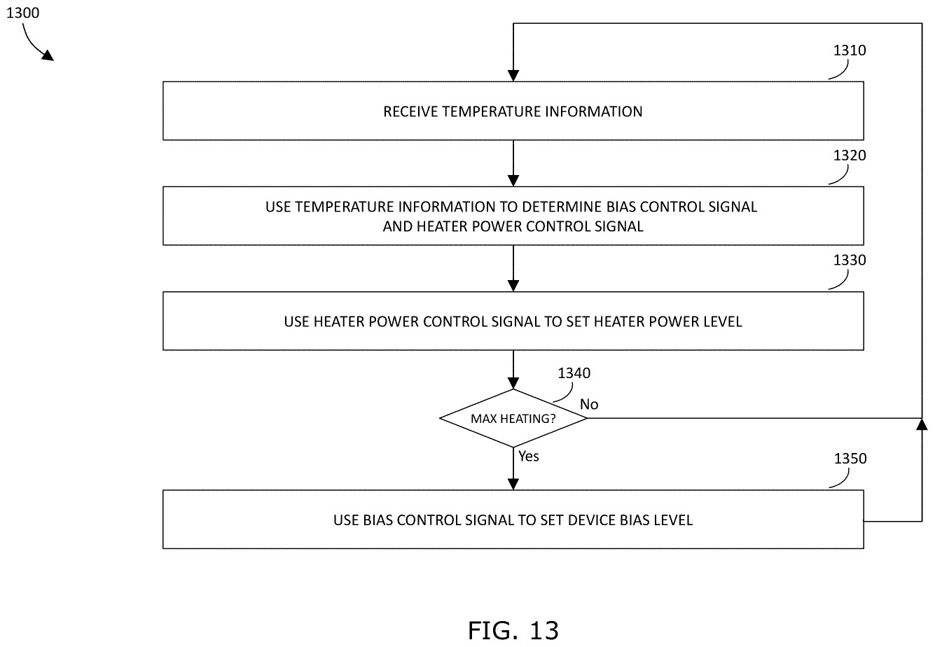

FIG. 13 illustrates another example method 1300 of temperature compensation in a PIC that includes a modulator and/or a photodetector. Method 1300 includes:
1310—receiving temperature information. In some implementations, the temperature information includes a device temperature (the local temperature of the modulator and/or the photodetector). The implementation reads, estimates, or predicts the device temperature from the temperature information. In other or further implementations, the temperature information includes a PIC or package temperature.
1320—using the temperature information to determine a heater power control signal and a bias control signal. An implementation may send the heater power control signal and the bias control signal to a heater power source and a bias source. Some implementations compare the device temperature with the target maximum operating temperature and use the difference between the device temperature and the target maximum operating temperature as a table address to find the heater power control signal or as an operand to calculate the heater power control signal. Other implementations look up or calculate the heater power control signal based on the difference between the PIC temperature and the target maximum operating temperature. An implementation may limit the heater power control signal to prevent short-term or long-term damage.

Although implementations may use a temperature difference to determine the heater power control signal, they use the device temperature itself (measured, estimated, or predicted) to determine the bias control signal. An implementation may determine the bias control signal from a temperature model (i.e., by calculation) or from a table.
1330—using the heater power control signal to set a heater power level. An implementation may send the heater power control signal to a heater power source. The heater power source uses the heater power control signal to generate heater power. The implementation applies the heater power to a heater. The heater locally heats the modulator and/or the photodetector. The heater is located within 30 microns from the modulator and/or the photodetector. In some implementations, the heater is located between 400 and 3000 nanometers directly above or below the modulator and/or the photodetector.
1340—determining if the heater power is at a maximum level. The implementation limits the heater power to prevent reliability problems due to, for example, electromigration of the metal in the heater. It may also limit the heater power for efficiency reasons. Upon determining that the heater power is not at the maximum level, method 1300 returns to 1310.
1350—based on determining that the heater power is at the maximum level, using the bias control signal to modify a modulator bias level and/or a photodetector bias level. Some implementations modify only the modulator bias level, whereas other implementations modify both the modulator bias level and the photodetector bias level.

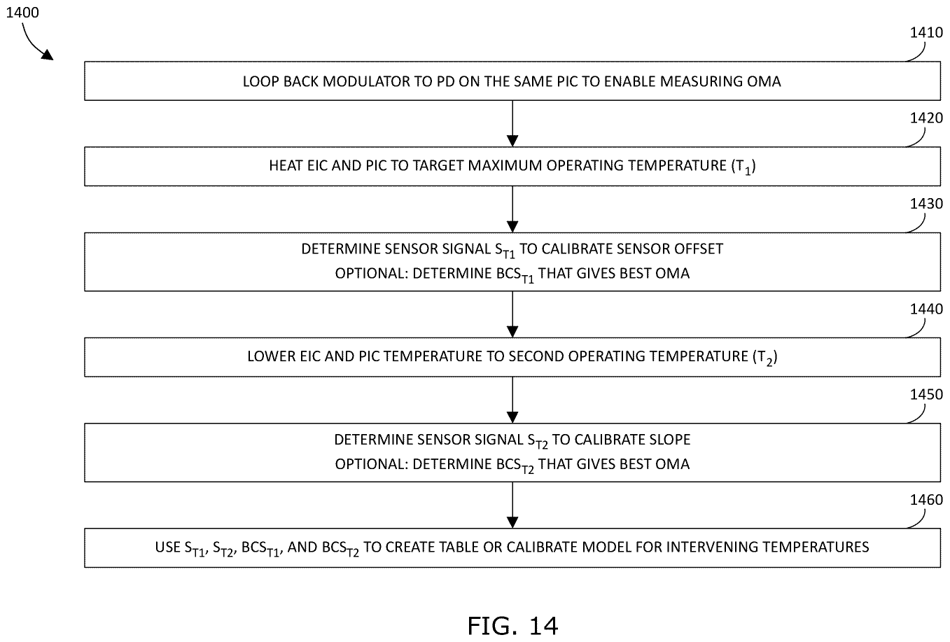

FIG. 14 illustrates an example method 1400 of calibrating a thermal control system in a package that includes a PIC and an EIC. The PIC includes a modulator and a photodiode. The package includes a sensor (e.g., in the PIC and/or in the EIC). The calibration may take place during or with production testing or at any other time. Method 1400 comprises:
1410—looping back the modulator to the photodetector to enable measuring an OMA of the modulator. Looping back means photonically routing a modulator output signal to the input of the photodetector, so that the photodetector measures the modulator output signal. Looping back may use waveguides internal to the PIC, and/or optical fibers connected to the PIC.
1420—raising the temperature of the PIC and the EIC to a target operating temperature (T₁) and letting the PIC and EIC reach thermal equilibrium.
1430—determining a first sensor signal (S_{T1}) to calibrate a sensor offset. Some implementations further determine a first bias control signal (BCS_{T1}) that (when applying the associated bias to the modulator) results in a first optimum OMA.
1440—lowering the temperature of the PIC and the EIC to a second operating temperature (T₂) and letting the PIC and EIC reach thermal equilibrium.
1450—determining a second sensor signal (S_{T2}) to calibrate a sensor sensitivity slope. Some implementations further determine a second bias control signal (BCS_{T2}) that (when applying the associated bias to the modulator) results in a second optimum OMA.
1460—using S_{T1} and S_{T2} to create a table or calibrate a model for operating temperatures between T₁ and T₂. Some implementations further use BCS_{T1} and BCS_{T2} to create the table or to calibrate the model. For example, an implementation may store the table in memory 374 (which may be nonvolatile), and the table holds rows of values, each row including a measured temperature value and an associated bias control signal. In some implementations, the row further holds an associated heater power control signal.

### PARTICULAR IMPLEMENTATIONS

Described implementations of the subject matter can include one or more features, alone or in combination, as described in the following clauses.

Clause 1. A package comprising:
a substrate configured to be electrically coupled with a heater power source on a first substrate side;
a photonic integrated circuit (PIC) including a modulator with a first heater and a photodetector with a second heater, the PIC having a first side electrically coupled with a second side of the substrate; and
an electronic integrated circuit (EIC) including a temperature controller configured to control localized heating of the modulator by the first heater in response to determining a first condition and/or localized heating of the photodetector by the second heater in response to determining a second condition, wherein the EIC has a first side coupled with a second side of the PIC.
   Clause 2. The package of clause 1, wherein:
the PIC includes at least a part of a first temperature sensor to determine a first temperature and/or a second temperature.
   Clause 3. The package of clause 1 or clause 2, wherein:
the first condition includes that a first temperature is lower than a target operating temperature; and/or
the second condition includes that a second temperature is lower than the target operating temperature.
   Clause 4. The package of any of the clauses 1 to 3, wherein:
the first temperature is related to a modulator temperature and/or the second temperature is related to a photodetector temperature.
   Clause 5. The package of any of the clauses 1 to 4, wherein:
the temperature controller is configured to control a bias of the modulator while limiting localized heating of the modulator to a modulator heating maximum in response to determining that the first temperature is in an extended operating temperature range.
   Clause 6. The package of any of the clauses 1 to 5, wherein:
the modulator is an electroabsorption modulator (EAM) and the bias of the modulator is a negative voltage.
   Clause 7. The package of any of the clauses 1 to 6, wherein:
the temperature controller is configured to limit localized heating of the photodetector to a photodetector heating maximum in response to determining that the second temperature is in an extended operating temperature range.
   Clause 8. The package of any of the clauses 1 to 7, wherein:
the temperature controller is configured to control a bias of the photodetector in response to determining that the second temperature is in an extended operating temperature range.
   Clause 9. The package of any of the clauses 1 to 8, wherein the temperature controller is configured to cause the heater power source to modify an amount of power that the first heater and/or the second heater receives from the heater power source.
   Clause 10. The package of any of the clauses 1 to 9, wherein:
the first heater is located within thirty (30) microns of the modulator and the second heater is located within thirty (30) microns of the photodetector.
   Clause 11. The package of any of the clauses 1 to 10, wherein:
the first heater is located between two hundred (200) and three thousand (3,000) nanometers directly above or below the modulator and the second heater is located between two hundred (200) and three thousand (3,000) nanometers directly above or below the photodetector.
   Clause 12. The package of any of the clauses 1 to 11, wherein:
the package includes a second temperature sensor to determine an average PIC temperature.
   Clause 13. The package of any of the clauses 1 to 12, mounted on a circuit board, wherein the substrate is electrically coupled with the circuit board on the first side of the substrate, and wherein a third temperature sensor is mounted on the circuit board and electrically coupled with the temperature controller via the circuit board.
   Clause 14. The package of any of the clauses 1 to 13, wherein:
the package includes an interposer mounted on the substrate;
the package includes a processor mounted on the interposer;
the PIC is mounted on the interposer; and
the EIC is mounted on the PIC.
   Clause 15. The package of any of the clauses 1 to 13, wherein:
the PIC is mounted on the substrate;
the package includes a processor mounted on the PIC; and
the EIC is mounted on the PIC.
   Clause 16. A method of temperature compensation in a PIC that includes a modulator and/or a photodetector, the method comprising:
determining a sensed temperature in or near the PIC, wherein the sensed temperature is representative of a device temperature (a temperature of the modulator and/or the photodetector); and
communicating the sensed temperature from the PIC to a temperature controller in an EIC and performing a first action, a second action, or both, based on the sensed temperature;
wherein the first action includes:
   (1) determining a heater power control signal;
   (2) communicating the heater power control signal to a heater power source;
   (3) in the heater power source, generating heater power based on the heater power control signal; and
   (4) applying the heater power to a heater positioned near the modulator and/or the photodetector;
and wherein the second action includes:
   (5) determining a device bias control signal;
   (6) communicating the device bias control signal to a bias source;
   (7) in the bias source, generating a bias based on the device bias control signal; and
   (8) applying the bias to the photodetector and/or the modulator.
      Clause 17. The method of clause 16, wherein the temperature controller performs at least one of reading, estimating, or predicting the temperature of the modulator and/or the photodetector.
      Clause 18. The method of clause 16 or clause 17, further comprising:
determining if the device temperature is within an extended range; and
based on determining that the device temperature is within the extended range,
   (9) keeping the heater at a maximum heater power.
      Clause 19. A method of temperature compensation in a PIC that includes a modulator and/or a photodetector, the method comprising:
receiving temperature information;
using the temperature information to determine a heater power control signal and a bias control signal;
using the heater power control signal to generate heater power and applying the heater power to a heater, wherein the heater locally heats the modulator and/or the photodetector;
determining if the heater power is at a maximum level; and
based on determining that the heater power is at the maximum level, using the bias control signal to modify a modulator bias level and/or a photodetector bias level.
   Clause 20. The method of clause 19, wherein:

using the temperature information includes at least one of reading, estimating, or predicting a device temperature from the temperature information, wherein the device temperature is a temperature of the modulator and/or the photodetector.

Clause 21. A method of calibrating a thermal control system in a package that includes a temperature sensor, a PIC and an EIC, and wherein the PIC includes a modulator and a photodetector, the method comprising:
looping back the modulator to the photodetector to enable measuring an optical modulation amplitude (OMA) of the modulator;
setting a temperature of the PIC and the EIC at a target operating temperature (T₁) and letting the PIC and EIC reach thermal equilibrium;
determining a first sensor signal (S_{T1}) to calibrate a sensor offset;
setting the temperature of the PIC and the EIC at a second operating temperature (T₂) and letting the PIC and EIC reach thermal equilibrium;
determining a second sensor signal (S_{T2}) to calibrate a sensor sensitivity slope; and
using S_{T1} and S_{T2} to create a table or calibrate a model for operating temperatures between T₁ and T₂.
   Clause 22. The method of clause 21, further comprising:
at the target operating temperature (T₁), determining a first bias control signal (BCS_{T1}) that (when applying an associated bias to the modulator) results in a first optimum OMA;
at the second operating temperature (T₂), determining a second bias control signal (BCS_{T2}) that (when applying an associated bias to the modulator) results in a second optimum OMA; and
using BCS_{T1} and BCS_{T2} to create at least a part of the table or to calibrate at least a part of the model.

### CONSIDERATIONS

Although the description has been described with respect to specific implementations thereof, these specific implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above. For example, temperature controller 370 may be a microcontroller, an optimized digital signal processor (DSP), a dedicated (i.e., hardwired) digital circuit, a configured digital circuit (e.g., in an FPGA), and any other circuit that can perform the functions described herein. Also, although this specification mentions specific sizes and distances, those may change with the applied manufacturing technology.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although the description has been described with respect to specific implementations thereof, these specific implementations are merely illustrative, and not restrictive. For instance, many of the operations can be implemented on a printed circuit board using off-the-shelf devices, in a System-on-Chip (SoC), application-specific integrated circuit (ASIC), programmable processor, a CGRA, or in a programmable logic device such as an FPGA, obviating the need for at least part of any dedicated hardware. Implementations may be as a single chip, or as a multi-chip module (MCM) packaging multiple semiconductor dies in a single package. All such variations and modifications are to be considered within the ambit of the disclosed technology the nature of which is to be determined from the foregoing description.

Any suitable technology for manufacturing electronic devices can be used to implement the circuits of specific implementations, including CMOS, FinFET, GAAFET, BiCMOS, bipolar, JFET, MOS, NMOS, PMOS, HBT, MESFET, etc. Different semiconductor materials can be employed, such as silicon, germanium, SiGe, GeSi, GaAs, InP, GaN, SiC, graphene, etc. Circuits may have single-ended or differential inputs, and single-ended or differential outputs. Terminals to circuits may function as inputs, outputs, both, or be in a high-impedance state, or they may function to receive supply power, a ground reference, a reference voltage, a reference current, or other. Although the physical processing of signals may be presented in a specific order, this order may be changed in different specific implementations. In some specific implementations, multiple elements, devices, or circuits shown as sequential in this specification can operate in parallel.

Different integration technologies can be used for a PIC, such as silicon photonics, InP, silicon nitride, hybrid and heterogeneous integration technologies, etc. Implementations may use different technologies for optical modulators, including Mach-Zehnder, microring resonator, SiGe electroabsorption modulator, Franz-Keldysh electroabsorption modulators, a quantum-confined Start effect (QCSE) electroabsorption modulator, a quantum well cell (QWC), etc. PICs may operate at any wavelength band. Any type of laser source can be employed, like distributed feedback lasers, laser diodes, hybrid integrated InP lasers, multiwavelength laser sources, microcomb light generator sources, etc. Different technologies can be implemented for photodiodes, such as SiGe electro-absorption photodiodes, InP photodiodes, avalanche photodiodes, etc.

It will also be appreciated that one or more of the elements depicted in the drawings/figures can also be implemented in a more separated or integrated manner, or even removed or rendered as inoperable in certain cases, as is useful in accordance with a particular application.

Thus, while specific implementations have been described herein, latitudes of modification, various changes, and substitutions are intended in the foregoing disclosures, and it will be appreciated that in some instances some features of specific implementations will be employed without a corresponding use of other features without departing from the scope and spirit as set forth. Therefore, many modifications may be made to adapt a particular situation or material to the essential scope and spirit.

1. A package comprising:
a substrate configured to be electrically coupled with a heater power source on a first substrate side;
a photonic integrated circuit (PIC) including a modulator with a first heater and a photodetector with a second heater, the PIC having a first side electrically coupled with a second side of the substrate; and
an electronic integrated circuit (EIC) including a temperature controller configured to control localized heating of the modulator by the first heater in response to determining a first condition and/or localized heating of the photodetector by the second heater in response to determining a second condition, wherein the EIC has a first side electrically coupled with a second side of the PIC.

2. The package of claim 1, wherein:
the PIC includes at least a part of a first temperature sensor to determine a first temperature and/or a second temperature.

3. The package of claim 1, wherein:
the first condition includes that a first temperature is lower than a target operating temperature; and/or
the second condition includes that a second temperature is lower than the target operating temperature.

4. The package of claim 3, wherein:
the first temperature is related to a modulator temperature and/or the second temperature is related to a photodetector temperature.

5. The package of claim 3, wherein:
the temperature controller is configured to control a bias of the modulator while limiting localized heating of the modulator to a modulator heating maximum in response to determining that the first temperature is in an extended operating temperature range.

6. The package of claim 5, wherein:
the modulator is an electroabsorption modulator (EAM) and the bias of the modulator is a negative voltage.

7. The package of claim 3, wherein:
the temperature controller is configured to limit localized heating of the photodetector to a photodetector heating maximum in response to determining that the second temperature is in an extended operating temperature range.

8. The package of claim 3, wherein:
the temperature controller is configured to control a bias of the photodetector in response to determining that the second temperature is in an extended operating temperature range.

9. The package of claim 3, wherein the temperature controller is configured to cause the heater power source to modify an amount of power that the first heater and/or the second heater receives from the heater power source.

10. The package of claim 1, wherein:
the first heater is located within thirty (30) microns of the modulator and the second heater is located within thirty (30) microns of the photodetector.

11. The package of claim 10, wherein:
the first heater is located between two hundred (200) and three thousand (3,000) nanometers directly above or below the modulator and the second heater is located between two hundred (200) and three thousand (3,000) nanometers directly above or below the photodetector.

12. The package of claim 1, wherein:
the package includes a second temperature sensor to determine an average PIC temperature.

13. The package of claim 1, mounted on a circuit board, wherein the substrate is electrically coupled with the circuit board on the first side of the substrate, and wherein a third temperature sensor is mounted on the circuit board and electrically coupled with the temperature controller via the circuit board.

14. The package of claim 1, wherein:
the package includes an interposer mounted on the substrate;
the package includes a processor mounted on the interposer;
the PIC is mounted on the interposer; and
the EIC is mounted on the PIC.

15. The package of claim 1, wherein:
the PIC is mounted on the substrate;
the package includes a processor mounted on the PIC; and
the EIC is mounted on the PIC.

16. A method of temperature compensation in a PIC that includes a modulator and/or a photodetector, the method comprising:
determining a sensed temperature in or near the PIC, wherein the sensed temperature is representative of a device temperature (a temperature of the modulator and/or the photodetector); and
communicating the sensed temperature from the PIC to a temperature controller in an EIC and performing a first action, a second action, or both, based on the sensed temperature;
wherein the first action includes:
(1) determining a heater power control signal;
(2) communicating the heater power control signal to a heater power source;
(3) in the heater power source, generating heater power based on the heater power control signal; and
(4) applying the heater power to a heater positioned near the modulator and/or the photodetector;
and wherein the second action includes:
(5) determining a device bias control signal;
(6) communicating the device bias control signal to a bias source;
(7) in the bias source, generating a bias based on the device bias control signal; and
(8) applying the bias to the photodetector and/or the modulator.

17. The method of claim 16, wherein the temperature controller performs at least one of reading, estimating, or predicting the temperature of the modulator and/or the photodetector.

18. The method of claim 16, further comprising:
determining if the device temperature is within an extended range; and
based on determining that the device temperature is within the extended range,
(9) keeping the heater at a maximum heater power.

19. A method of temperature compensation in a PIC that includes a modulator and/or a photodetector, the method comprising:
receiving temperature information;
using the temperature information to determine a heater power control signal and a bias control signal;
using the heater power control signal to generate heater power and applying the heater power to a heater, wherein the heater locally heats the modulator and/or the photodetector;
determining if the heater power is at a maximum level; and
based on determining that the heater power is at the maximum level, using the bias control signal to modify a modulator bias level and/or a photodetector bias level.

20. The method of claim 19, wherein:
using the temperature information includes at least one of reading, estimating, or predicting a device temperature from the temperature information, wherein the device temperature is a temperature of the modulator and/or the photodetector.

21. A method of calibrating a thermal control system in a package that includes a temperature sensor, a PIC and an EIC, and wherein the PIC includes a modulator and a photodetector, the method comprising:
looping back the modulator to the photodetector to enable measuring an optical modulation amplitude (OMA) of the modulator;
setting a temperature of the PIC and the EIC at a target operating temperature (T₁) and letting the PIC and EIC reach thermal equilibrium;
determining a first sensor signal (S_{T1}) to calibrate a sensor offset;
setting the temperature of the PIC and the EIC at a second operating temperature (T₂) and letting the PIC and EIC reach thermal equilibrium;
determining a second sensor signal (S_{T2}) to calibrate a sensor sensitivity slope; and
using S_{T1} and S_{T2} to create a table or calibrate a model for operating temperatures between T₁ and T₂.

22. The method of claim 21, further comprising:
at the target operating temperature (T₁), determining a first bias control signal (BCS_{T1}) that (when applying an associated bias to the modulator) results in a first optimum OMA;
at the second operating temperature (T₂), determining a second bias control signal (BCS_{T2}) that (when applying an associated bias to the modulator) results in a second optimum OMA; and
using BCS_{T1} and BCS_{T2} to create at least a part of the table or to calibrate at least a part of the model.
